(19) United States
(12) Patent Application Publication
(10) Pub. No.: US 2010/0245133 A1
(43) Pub. Date: Sep. 30, 2010

(54) KEY SHEET

(75) Inventors: Koji Yamashita, Tokyo (JP); Masatoshi Wakisaka, Tokyo (JP)

Correspondence Address: HEDMAN & COSTIGAN, P.C., 1230 AVENUE OF THE AMERICAS, 7th floor, NEW YORK, NY, 10020, US

(73) Assignee: Sunarrow Ltd., Chuo-ku, Tokyo (JP)

(21) Appl. No.: 12/734,057

(22) PCT Filed: Sep. 29, 2008
(86) PCT No.: PCT/JP2008/067649

§ 371 Date: Apr. 6, 2010

(30) Foreign Application Priority Data
Oct. 29, 2007 (JP) 2007-281020

(51) Int. Cl. H03M 11/00

(52) U.S. Cl. 341/22

(57) ABSTRACT

An object of the present invention is to provide a satisfactorily operable key sheet having a structure which entirely has rigidity and shape stability but which is capable of increasing the degree of freedom in the selection of a material, thickness or the like. The key sheet according to the present invention is a key sheet having a plurality of keys, including a metal plate, and a key top portion secured to the surface of the metal plate so as to cover a large part of the metal plate, and the key top portion has a sheet-like base portion and the plurality of keys each formed in a protruding shape on the surface of this sheet-like base portion.

### BACKGROUND OF THE INVENTION

1. Field of the Invention

The present invention relates to a key sheet for use in an electronic device such as a portable phone (including a so-called PHS), a portable information terminal (a personal digital assistance (PDA) or the like), a portable audio, a remote controller for a household electric appliance or a keyboard.

2. Description of the Related Art

Heretofore, a key sheet using a metal plate has been developed. For example, in Japanese Patent Application Laid-Open No. 2006-156333, a cover sheet for a push button switch is disclosed in which an operation plate made of a metal is provided with a partition groove forming a pressable/displaceable pressing operation piece (see the drawings and the like of Japanese Patent Application Laid-Open No. 2006-156333).

Moreover, in Japanese Patent Application Laid-Open No. 2006-244924, a cover sheet for a push button switch is disclosed in which a reinforcing piece constituted of a polymer material is provided adjacent to a metal thin plate in the plate thickness direction of the metal thin plate (see the drawings and the like of Japanese Patent Application Laid-Open No. 2006-244924).

In the cover sheet for the push button switch of Japanese Patent Application Laid-Open No. 2006-156333, the operation plate made of the metal imparts rigidity and shape stability to the whole cover sheet for the push button switch (see [0038] and the like of Japanese Patent Application Laid-Open No. 2006-156333). Therefore, there has been a restriction on the selection of the material, the thickness or the like of this operation plate made of the metal. Furthermore, in the cover sheet for the push button switch of Japanese Patent Application Laid-Open No. 2006-156333, the surface of the operation plate or the surface of a coating layer is flat (see FIGS. 2, 10 and the like of Japanese Patent Application Laid-Open No. 2006-156333). Therefore, when this operation plate is touched, a boundary between the keys cannot be recognized, and a region other than the key is sometimes pressed. Moreover, although a specific key is to be pressed, another adjacent key is sometimes pressed to cause reaction (the pressing of the wrong key), and this cover sheet for the push button switch has poor operability.

In the cover sheet for the push button switch of Japanese Patent Application Laid-Open No. 2006-244924, the metal thin plate imparts the rigidity and the shape stability to the whole cover sheet for the push button switch (see [0020] and the like of Japanese Patent Application Laid-Open No. 2006-244924). Therefore, there has been a restriction on the selection of the material, the thickness or the like of this metal thin plate. Moreover, the reinforcing piece has a function of imparting the shape stability so as to prevent the flexure, indentation or the like of the metal thin plate (see [0020] and the like of Japanese Patent Application Laid-Open No. 2006-244924), and hence there has been a restriction on the selection of the material, the thickness or the like of this reinforcing piece. Moreover, when the reinforcing piece is made of a film-like resin, the degree of the covering of the metal thin plate with this reinforcing piece is not clear. Furthermore, since the metal thin plate imparts the rigidity and the shape stability to the whole cover sheet for the push button switch, the reinforcing piece does not impart the rigidity or the shape stability to the whole cover sheet for the push button switch.

### SUMMARY OF THE INVENTION

The present invention has been developed in view of the above problem, and an object thereof is to provide a satisfactorily operable key sheet having a structure which entirely has rigidity and shape stability but which is capable of increasing the degree of freedom in the selection of a material, thickness or the like.

To solve the above problem, a key sheet according to the present invention is a key sheet having a plurality of keys, comprising: a metal plate; and a key top portion secured to the surface of the metal plate so as to cover a large part of the metal plate, characterized in that the key top portion has a sheet-like base portion and the plurality of keys each formed in a protruding shape on the surface of this sheet-like base portion.

The key sheet according to the present invention has the metal plate, and the key top portion secured to the surface of the metal plate so as to cover the large part of the metal plate, and hence the key top portion is secured to cover the large part of the metal plate. Therefore, in a case where the material, the thickness or the like of one of the key top portion and the metal plate is determined so that one of the key top portion and the metal plate has rigidity and shape stability, the rigidity and the shape stability can be imparted to the whole key sheet. The material, the thickness or the like of the other member (the key top portion or the metal plate) can appropriately be determined without being restricted by the rigidity, the shape stability or the like. Therefore, the degree of freedom in the selection of the material, the thickness or the like of the other member can be increased. That is, one member can impart the rigidity and the shape stability to the whole key sheet. Moreover, in a case where the materials, the thicknesses or the like of the key top portion and the metal plate are determined so that the whole key sheet has the rigidity and the shape stability, the degree of the freedom in the selection of the materials, the thicknesses or the like of the key top portion and the metal plate can be increased. Thus, the structure in which the key top portion is secured to the metal plate so as to cover the large part of the metal plate is a structure entirely having the rigidity and the shape stability but capable of increasing the degree of the freedom in the selection of the material, the thickness or the like. Furthermore, the key top portion has the sheet-like base portion and the plurality of keys formed in the protruding shape on the surface of this sheet-like base portion, respectively, and the keys formed in the protruding shape constitute protruding portions, respectively. The protruding portions constitute the three-dimensional surface of this key sheet. Furthermore, since the protruding portions constitute the keys, a boundary between the keys becomes clear, and the keys can clearly be recognized. Therefore, the pressing of a region other than the key or the pressing of the wrong key is not caused, and hence the key sheet has satisfactory operability.

Moreover, the key sheet is characterized in that the metal plate has a plurality of display portions corresponding to the plurality of keys, respectively, and that the key top portion has light transmitting properties so that at least a part of the metal plate including the display portions is visually recognized via this key top portion.

Since the metal plate has the plurality of display portions corresponding to the plurality of keys, respectively, and the key top portion has the light transmitting properties so that at least a part of the metal plate including the display portions is visually recognized via this key top portion, at least a part of the metal plate including the display portions is visually recognized via the key top portion, and the key sheet has a metallic color.

Moreover, the key sheet is characterized in that the keys are positioned away from one another.

Since the keys are positioned away from one another, the displacement of the key during a pressing operation can be increased, and an influence on the adjacent key can be decreased or eliminated. If the keys are disposed very close to one another, during the tilt or downward movement of the key, the displacement is sometimes decreased owing to the influence of the adjacent key, or even the adjacent key is sometimes influenced to tilt or move downwards. However, this key sheet can prevent this problem. Moreover, when the keys are positioned away from one another, a three-dimensional effect increases.

Moreover, the key sheet according to the present invention is characterized in that a character, a symbol or a figure of the display portion is formed of a set of a large number of light transmitting holes.

Since the character, the symbol or the figure of the display portion is formed of the set of the large number of light transmitting holes, this display portion gives a new impression. Furthermore, in a case where the character or the like of this display portion is a character or the like having a region (a so-called kanji character “shima (island)”) which falls when represented by one through hole, this character or the like does not have to be represented by the through hole having a cut character shape or the like, so that the display portion giving the new impression can be formed. Therefore, this key sheet can be a key sheet giving a newer impression.

Moreover, the key sheet according to the present invention is characterized in that the light transmitting holes are slit-like light transmitting holes.

Since the light transmitting holes are the slit-like light transmitting holes, this display portion gives a newer impression.

Furthermore, the key sheet according to the present invention is characterized in that the light transmitting holes are worm-eaten light transmitting holes.

Since the light transmitting holes are the worm-eaten light transmitting holes, this display portion gives a newer impression.

In addition, the key sheet according to the present invention is characterized in that at least a part of the peripheries of the light transmitting holes is colored.

Since at least a part of the peripheries of the light transmitting holes is colored, the display portion becomes colorful, and the display portion gives a new impression. In particular, owing to the synergetic effect of the colored region and the light transmitting holes, the display portion gives a newer impression. Therefore, this key sheet is a metallic key sheet having a newer design.

Moreover, the key sheet according to the present invention is characterized in that a plurality of pressing pieces are disposed on the back surface side of the metal plate.

Since this key sheet has the pressing pieces on the back surface side of the metal plate, the pressing pieces can press click sense generating portions for generating a click sense, so that an electronic device using this key sheet can generate the click sense.

As described above, the key sheet according to the present invention has the structure entirely having the rigidity and shape stability but capable of increasing the degree of the freedom in the selection of the material, the thickness or the like, and the key sheet also has satisfactory operability.

### BRIEF DESCRIPTION OF THE DRAWINGS

FIG. 1 is a schematic perspective view of a key sheet according to a first embodiment of the present invention;

FIG. 2 is an explanatory view showing a sectional constitution of the key sheet according to the first embodiment of the present invention;

FIG. 3 is an explanatory view showing a numeral 4 (before colored) of a display portion of the key sheet according to the first embodiment of the present invention;

FIG. 4 is an explanatory view showing the numeral 4 (after colored) of the display portion of the key sheet according to the first embodiment of the present invention;

FIG. 5 is an explanatory view showing a sectional constitution of the key sheet according to a second embodiment of the present invention;

FIG. 6 is an explanatory view showing a numeral 4 (before colored) of a display portion of a key sheet according to a modification of the first or second embodiment of the present invention; and

FIG. 7 is an explanatory view showing the numeral 4 (after colored) of the display portion of the key sheet according to the modification of the first or second embodiment of the present invention.

### DESCRIPTION OF THE PREFERRED EMBODIMENT

Embodiments of the present invention will be described with reference to the drawings. It is to be noted that in the drawings, similar, corresponding or generic parts are sometimes denoted with the same reference numerals when described. The present invention is not limited to the following embodiments. Needless to say, the following embodiments can be changed (e.g., the omission or addition of constitutional requirements (members, etc.), the changes of the shapes of the constitutional requirements, etc.) without departing from the scope of the present invention.

### First Embodiment

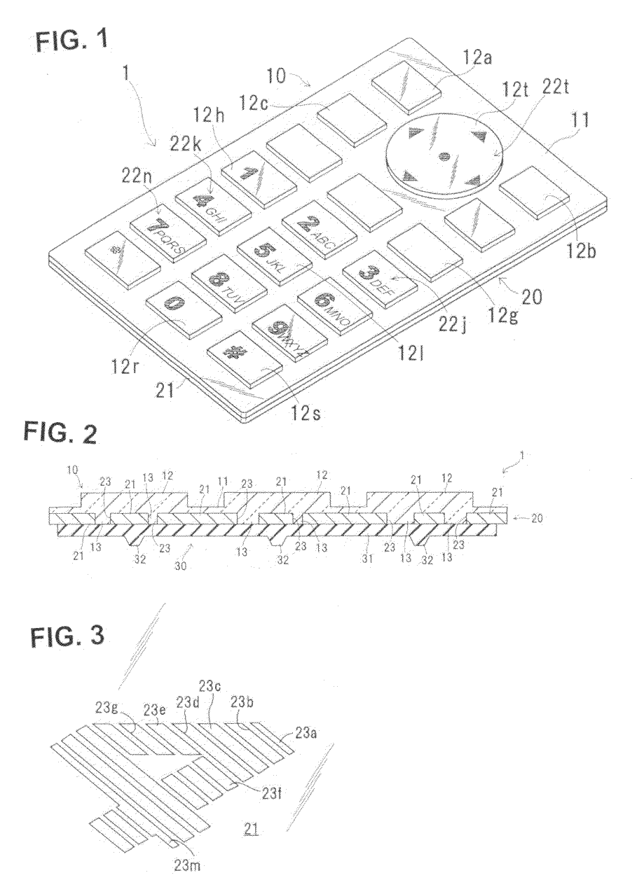

A key sheet 1 according to a first embodiment will be described with reference to FIGS. 1 to 4. It is to be noted that in FIG. 2, to describe a sectional constitution of the key sheet 1, slit-like light transmitting holes 23 or the like are shown so that they are easily seen. Moreover, in FIG. 2, constitutional requirements which can generically be referred are denoted with generic reference numerals (12, etc.).

It is to be noted that a key 12 is a generic representation of keys 12a, 12b, 12c, . . . , and is one of the plurality of keys. A display portion 22 is a generic representation of display portions 22a, 22b, 22c, . . . , and is one of the plurality of display portions. The slit-like light transmitting hole 23 is a generic representation of slit-like light transmitting holes 23a, 23b, 23c, . . . , and is one of the plurality of slit-like light transmitting holes.

As shown in FIGS. 1 and 2, the key sheet 1 according to the first embodiment has a plurality of keys 12 in predetermined positions. The key sheet 1 has a metal plate 20 having a quadrangular shape (including a substantially quadrangular shape having rounded or collapsed corners, this also applies to the following description), and a key top portion 10 secured to the surface of the metal plate 20 so as to cover a large part of the metal plate 20.

In the key sheet 1, the key top portion 10 is secured to cover the large part of the metal plate 20. In consequence, in a case where the material, the thickness or the like of one of the key top portion 10 and the metal plate 20 is determined so that one of the key top portion 10 and the metal plate 20 has rigidity and shape stability, the rigidity and the shape stability can be imparted to the whole key sheet 1. The material, the thickness or the like of the other member (the key top portion 10 or the metal plate 20) can appropriately be determined without being restricted by the rigidity, the shape stability or the like. Therefore, the degree of freedom in the selection of the material, the thickness or the like of the other member can be increased. That is, one member can impart the rigidity and the shape stability to the whole key sheet 1. Moreover, in a case where the materials, the thicknesses or the like of the key top portion 10 and the metal plate 20 are determined so that the whole key sheet 1 has the rigidity and the shape stability, the degree of the freedom in the selection of the materials, the thicknesses or the like of the key top portion 10 and the metal plate 20 can be increased. Thus, a structure in which the key top portion 10 is secured to the metal plate 20 so as to cover the large part of the metal plate 20 is a structure entirely having the rigidity and the shape stability but capable of increasing the degree of the freedom in the selection of the material, the thickness or the like. For example, when the key top portion 10 is hard and the key top portion 10 imparts the rigidity and the shape stability to the whole key sheet 1, a soft metal can be used in the metal plate 20, and the thickness of the metal plate 20 can be decreased. Moreover, for example, when the metal plate 20 imparts the rigidity and the shape stability to the whole key sheet 1, a sheet-like base portion 11 is formed of a soft material, and the thickness of the sheet-like base portion 11 can be decreased. Thus, a structure in which the key top portion 10 covers the large part of the metal plate 20 is the structure entirely having the rigidity and the shape stability but capable of increasing the degree of the freedom in the selection of the material, the thickness or the like. Moreover, the metal plate 20 can be prevented from being damaged.

The key top portion 10 has the sheet-like base portion 11 and the plurality of keys 12 formed in the protruding shape on the surface of this sheet-like base portion 11, respectively.

The plurality of keys 12 are connected to the sheet-like base portion 11, and the key top portion 10 has a one-sheet-like shape. The keys formed in the protruding shape constitute protruding portions, and hence the key top portion 10 has a plurality of protruding portions. The protruding portions constitute the three-dimensional surface of this key sheet 1. Furthermore, since the protruding portions constitute the keys 12, a boundary between the keys 12 becomes clear, and the keys 12 can clearly be recognized. Therefore, the pressing of a region other than the key 12 or the pressing of the wrong key 12 is not caused, and hence the key sheet has satisfactory operability.

The keys 12 are keys such as a functional key, ten keys and a multidirectional key. As shown in FIG. 1, a key 12a is the functional key, keys 12h are the ten keys, and a key 12t is the multidirectional key (here also having a function of a determination key).

The shape of the key 12 may be a pillar shape such as a rectangular parallelepiped shape, a triangular pole shape or a columnar shape, and can appropriately be determined. There is not any special restriction on the height of the key, but when the height is set to a large height of, for example, 1.0 mm or more, a three-dimensional effect increases. Furthermore, when the height is set to a height above 2.0 mm (2.0 mm is not included), the three-dimensional effect further increases.

Moreover, the keys are positioned away from one another, so that the displacement of the key 12 during a pressing operation can be increased, or an influence on the adjacent key 12 can be decreased or eliminated. If the keys 12 are disposed very close to one another, during the tilt or downward movement of the key 12, the displacement is sometimes decreased owing to the influence of the adjacent key 12, or even the adjacent key 12 is sometimes influenced to tilt or move downwards. However, this key sheet 1 can prevent this problem. Moreover, when the keys are positioned away from one another, the three-dimensional effect increases. A distance between the keys disposed away from each other (a distance between the protruding portions) is set to, for example, 1.0 mm or more.

The key top portion 10 is hard. That is, the key top portion 10 is a hard key top portion. Furthermore, the key top portion 10 (the hard key top portion) preferably has flexibility and elasticity to such an extent that an operation of simultaneously pressing the plurality of keys is not disturbed.

The key top portion 10 is made of a hard synthetic resin as a material. For example, in the key top portion 10, a light transmitting electromagnetic setting resin such as an acrylic resin, an epoxy-based resin, a vinyl-based resin or a silicone-based resin may be used. Moreover, as a usual thermoplastic or thermosetting resin, a light transmitting resin such as a polyethylene terephthalate (PET) based resin, a polycarbonate (PC) based resin, a polyurethane based resin, an acrylic resin or a silicone based resin may be used. It is to be noted that the electromagnetic setting resin is a resin which sets when irradiated with an electromagnetic wave, and examples of the resin include an ultraviolet setting resin (a UV setting resin) and a visible ray setting resin.

The key top portion 10 is integrally made of a single hard synthetic resin as a material, and hence the sheet-like base portion 11 and the plurality of keys 12 are integrally formed. It is to be noted that the key top portion 10 may be formed as one member by appropriately combining one or more members, one or more layers or the like and superimposing them on one another especially in a thickness direction.

Various conditions such as the material, the thickness and the hardness of the key top portion 10 are determined so that this key top portion 10 imparts the rigidity and the shape stability to the whole key sheet 1. It is to be noted that when the metal plate 20 imparts the rigidity and the shape stability to the whole key sheet 1, especially the sheet-like base portion 11 of the key top portion 10 may have softness or may be thinned. However, to secure the satisfactory operability, the key 12 preferably has the hardness.

The key top portion 10 is secured to the surface of the metal plate 20 so as to cover a large part of the metal plate 20 including the display portion 22. Since the key top portion 10 has the sheet-like base portion 11 and the plurality of keys 12 formed in the protruding shape on the surface of the sheet-like base portion 11, the key top portion 10 covers even another region in addition to a region right under the key 12 of the metal plate 20. To cover the large part of the metal plate 20 also includes a case where the whole surface of the metal plate 20, for example, the same plane is covered. Moreover, for example, when the only key top portion 10 imparts the rigidity and the shape stability to the key sheet 1, the large part is a region (e.g., a region of 90% or more of the metal plate 20) having such a breadth that this imparting is not disturbed. Moreover, for example, when the metal plate 20 imparts the rigidity and the shape stability to the key sheet 1, the large part is a region including all of the plurality of display portions 22 and the plurality of keys 12. The display portions 22 will be described later in detail, but a plurality of display portions are formed on the metal plate 20 so as to correspond to the plurality of keys 12, respectively.

Moreover, the key top portion 10 is colored and transparent, or colorless and transparent so that the portion entirely has light transmitting properties. This key top portion 10 comes in contact with the metal plate 20, so that the metal plate 20 (especially the display portion 22) is visually recognized via the key top portion 10 (the sheet-like base portion 11 and the respective keys 12). In consequence, the whole key sheet 1 has a metallic color.

The key sheet 1 may have the light transmitting properties so that at least a part of the metal plate 20 including the display portion 22 can visually be recognized via this key top portion 10. For example, to cover another region except the display portion 22 of the metal plate 20 and a peripheral region around the metal plate (the peripheral region is, for example, the region right under the key 12), the key top portion 10 may be subjected to decoration such as painting, and may have a portion which does not have any light transmitting properties. When at least a part of the metal plate 20 including the display portion 22 is visually recognized via the key top portion, the key sheet 1 has the metallic color.

Here, “the metallic color” usually includes not only a silver color as a generic metallic color but also a chromatic metallic color obtained by appropriately coloring the metal plate 20 itself by various methods, for example, so-called metallic red, metallic green and the like. When the metallic color is the chromatic metallic color, the key top portion 10 is colorless and transparent, and the metal plate 20 has the above chromatic metallic color. Moreover, the key top portion 10 may be colored and transparent, and the metal plate 20 may have a metallic color such as the silver color, so that the whole key sheet has the chromatic metallic color.

It is to be noted that in the whole key sheet 1 (including the substantially whole key sheet in the present invention), when the whole metal plate 20 (including substantially the whole metal plate in the present invention) can visually be recognized via the key top portion 10, the key sheet 1 increasingly seems to have high quality. Moreover, such a key sheet 1 can inexpensively and easily be formed.

The key top portion 10 is directly formed on the surface of the metal plate 20 by a forming method such as printing (so-called gravure printing, mold printing or the like) on the surface of the metal plate 20 by use of the electromagnetic setting resin and a mold having a plurality of recess portions corresponding to the keys 12, or an insertion molding of inserting the metal plate 20 into the thermoplastic resin or the thermosetting resin. It is to be noted that when the electromagnetic setting resin is used as the material, to irradiate the material with the electromagnetic wave, a transparent mold or the like is used as the above mold.

According to such a forming method, the key top portion 10 is directly secured to the metal plate 20 in a case where a liquid material is hardened. It is to be noted that to increase securing strength, the surface of the metal plate 20 may be subjected to a chemical or physical surface (reforming) treatment prior to the formation of the key top portion 10.

Moreover, when the key top portion 10 is formed by such a forming method, the material invades light transmitting holes described later (in a case where deep holes are formed so that the holes transmit light, holes formed from a surface side are referred), for example, slit-like light transmitting holes 23, depending on miscellaneous conditions, for example, the viscosity of the liquid material of the key top portion 10. Therefore, a hole filling material 13 is formed, and the key sheet 1 has the hole filling material 13. Needless to say, the hole filling material 13 preferably has the light transmitting properties. All of the holes do not have to be filled with the hole filling material 13. This hole filling material 13 is sometimes not formed.

In the metal plate 20, one metal thin plate 21 is basically provided only with the plurality of display portions 22 corresponding to the plurality of keys 12, respectively. When the metal plate 20 imparts the rigidity and the shape stability to the whole key sheet 1, the metal thin plate 21 is preferably a metal having comparatively high hardness and having elasticity to a certain degree, for example, a stainless steel (SUS), titanium, copper or the like. However, in a case where this key top portion 10 imparts the rigidity and the shape stability to the whole key sheet 1 or the like, the metal thin plate 21 may be a metal which does not satisfy the above conditions, for example, a comparatively soft noble metal such as gold, silver or vanadium. Moreover, when the key top portion 10 imparts the rigidity and the shape stability to the whole key sheet 1 and the thinning of the key sheet 1 is intended, the metal plate 20 has a thickness of, for example, 0.1 mm or less, especially preferably less than 0.05 mm. The thickness of the metal plate 20 can appropriately be changed, and may be set to 0.1 mm or more, so that the metal plate 20 imparts the rigidity and the shape stability to the whole key sheet 1.

The display portion 22 represents the type of a command, a character (including a numeral) or the like to be input into an electronic device (here, a portable phone) incorporating the key sheet 1 at a time when the corresponding key is operated.

The display portion 22 has one or more characters, one or more symbols, one or more figures or a combination of them. For example, a display portion 22n has “7”, “P”, “Q”, “R” and “S”, a display portion 22j has “3”, “D”, “E” and “F”, and a display portion 22t has four triangular arrow figures directed four directions of upper, lower, left and right directions, and a circular figure positioned in the center. The display portions 22 basically have a one-to-one correspondence to the keys.

The display portion 22 is positioned so as to fall in a portion inside the region of the corresponding key 12 in a horizontal direction. Thus, the display portion 22 is positioned in such a portion that when the corresponding key 12 is operated, a key operator can recognize, by this display portion 22, the type of the command to be input into the electronic device and/or the character to be input into the electronic device. As long as this condition is satisfied, the display portion 22 may be disposed in a position where a part of the display portion protrudes from the above region or a position outside the above region.

As shown in FIG. 3, the character, the symbol or the figure of the display portion 22 is formed of a set of a large number of (five or more, preferably nine or more, further preferably 15 or more, this also applies to the following description) slit-like light transmitting holes 23. The slit-like light transmitting holes 23 are light transmitting holes having a slit-like shape (a set of through holes, deep holes formed so as to transmit the light or fine through holes formed by sputtering in the metal thin plate 21). This will be described in further detail. The character, the symbol or the figure of the display portion 22 is formed by arranging a plurality of linear slit-like light transmitting holes 23a, 23b, 23c, . . . (especially arranging the holes in parallel with one another). Here, the linear slit-like light transmitting hole 23 may have several recesses or protrusions as in the slit-like light transmitting hole 23.

The character, the symbol or the figure of the display portion 22 is formed of the light transmitting holes, whereby the display portion 22 is a light transmitting display portion having the light transmitting properties. It is to be noted that the character, the symbol or the figure of the display portion 22 may sometimes be formed of one or more light transmitting holes. The light transmitting holes are formed by an appropriate method such as etching.

Thus, when the display portion 22 has the light transmitting properties and the key sheet 1 is illuminated from the downside, the light passes through the character, the symbol or the figure of the display portion 22, and this character, the symbol or the figure can be recognized even in a dark place. It is to be noted that the display portion 22 may be formed on the metal thin plate 21 by painting, printing or the like.

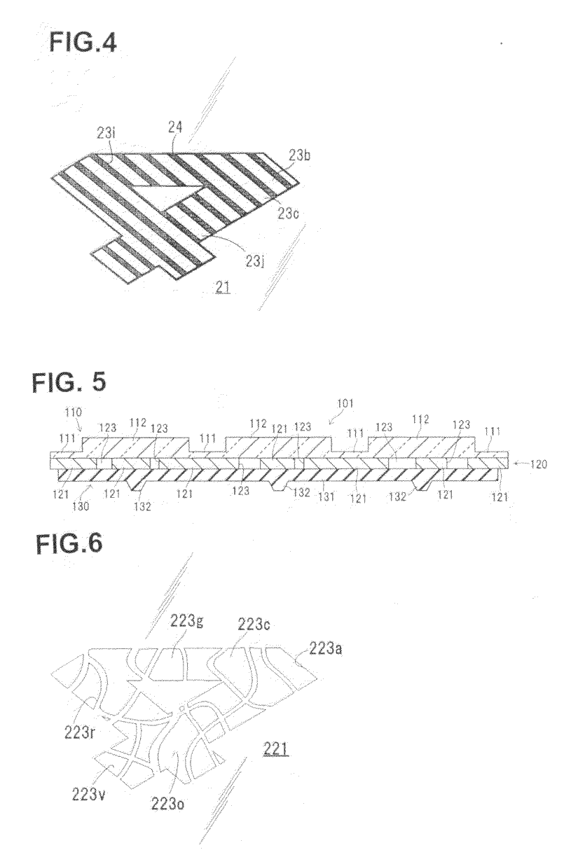

Furthermore, as shown in FIG. 4, all of the peripheries of the light transmitting holes is colored (it is to be noted that at least a part of them may be colored). This will be described in detail. A portion between the adjacent slit-like light transmitting holes 23 is colored. Furthermore, the periphery of the slit-like light transmitting hole 23 is colored so as to form the edge of a numeral “4”, that is, form the edge of the character, the symbol or the figure of the display portion 22. Therefore, the display portion 22 has a colored region 24 obtained by coloring the surface of the metal thin plate 21 by printing, painting, any type of film forming method or the like. It is to be noted that at least a part of the periphery of the light transmitting hole may be colored by, for example, one of the above coloring method. Moreover, another region of the surface of the metal thin plate 21 may be colored appropriately by the printing, the painting, any type of film forming method or the like for decoration. In this case, the metal plate 20 has a decorated region obtained by coloring the surface of the metal thin plate 21 for the decoration. Such a key sheet has novel design.

Moreover, at least a part of the surface of the metal thin plate 21 may be coated with a transparent material. In this case, the metal plate 20 has a coating region with which the surface (appropriately including the decorated region and/or the colored region) of the metal thin plate 21 is coated, but the surface of the coating region is referred to as the surface of the metal thin plate 21.

The key sheet 1 further has a pressing piece layer 30. The pressing piece layer 30 is constituted of a base portion 31 and a plurality of pressing pieces 32 positioned under the plurality of keys 12, respectively. The number of the pressing pieces 32 positioned under the respective keys 12 varies owing to the functions of the respective keys. For example, one pressing piece 32 corresponds to the ten keys or the like, but the pressing pieces 32 corresponding to the key 12t as the directional key are five pressing piece positioned in the center and upper, lower, left and right portions.

The pressing piece layer 30 is directly formed on the back surface of the metal plate 20, and is thus directly secured to the back surface of the metal plate 20. The pressing piece layer 30 may be formed as a separate member and then directly secured to the back surface of the metal plate 20 by appropriate securing means such as an adhesive or a sticky material. The pressing piece layer 30 may be secured to the back surface of the metal plate 20 via a certain member or layer, that is, may indirectly be secured. Thus, the pressing piece layer 30 is formed (secured) on the back surface side of the metal plate 20, and the pressing pieces 32 are formed on the back surface side of the metal plate 20. In consequence, the key sheet 1 has the plurality of pressing pieces 32 on the back surface side of the metal plate 20.

The pressing piece layer 30 is integrally formed of a silicone rubber, any type of elastomer material or any type of synthetic resin such as the electromagnetic setting resin as a material. The pressing piece layer 30 preferably has elasticity. The pressing piece layer 30 may be constituted of a plurality of pressing pieces 32 only, without disposing any base portion 31.

When the key sheet 1 is incorporated in a device, the pressing pieces 32 face click sense generating portions for generating a click sense with a space being left therebetween or abut on the click sense generating portions. The click sense generating portions can elastically be deformed and are provided on a substrate of the device. The click sense generating portions are, for example, switch portions each constituted of a metal dome, a contact for short-circuit or the like.

Since the key sheet 1 has the pressing piece 32 on the back surface side of the metal plate 20, the pressing piece 32 can press the click sense generating portion for generating the click sense, and hence the electronic device using this key sheet 1 can generate the click sense.

When the pressing piece layer 30 is directly formed on the back surface of the metal plate 20, the pressing piece layer 30 is integrally formed on the back surface of the metal plate 20 by an integral forming method such as printing (gravure printing, mold printing or the like) on the back surface of the metal plate 20 by use of a mold having a plurality of recess portions corresponding to the pressing pieces 32, or an insertion molding of inserting the metal plate 20. It is to be noted that when the electromagnetic setting resin is used as the material, to irradiate the material with the electromagnetic wave, a transparent mold or the like is used as the above mold. According to such a forming method, when the liquid material is hardened, the pressing piece layer 30 is directly secured to the metal plate 20. It is to be noted that to increase securing strength, the back surface of the metal plate 20 may be subjected to a chemical or physical surface (reforming) treatment prior to the formation of the pressing piece layer 30.

Moreover, when the pressing piece layer 30 is beforehand formed as a separate member and is then secured to the back surface of the metal plate 20, the pressing piece layer 30 is formed in a sheet-like shape having the pressing pieces 32 by injection or the like using a silicone rubber or any type of elastomer as a material, and this sheet is secured (directly secured or indirectly secured) to the back surface of the metal plate 20 by use of appropriate securing means such as an adhesive or a sticky material. It is to be noted that a film material made of PET or PC is provided with the pressing pieces 32 using the electromagnetic setting resin may be secured to the back surface of the metal plate 20 by use of appropriate securing means such as the adhesive or the sticky material on the back surface of the metal plate 20. To increase the securing strength, the back surface of the metal plate 20 and/or the surface (the upper surface in FIG. 2) of the pressing piece layer 30 may be subjected to the chemical or physical surface (reforming) treatment.

One of the key top portion 10 and the pressing piece layer 30 may first be formed, but the pressing piece layer 30 may be formed simultaneously with the key top portion 10. In this case, the pressing piece layer 30 and the key top portion 10 may integrally be formed via the metal plate 20. Furthermore, the pressing piece layer 30 and the key top portion 10 may integrally be formed so as to enclose the metal plate 20.

Moreover, when the pressing piece layer 30 is directly formed on the back surface of the metal plate 20, the material sometimes invades light transmitting holes (in a case where the deep holes are formed so that the holes transmit light, holes formed from a back surface side are referred), for example, the slit-like light transmitting holes 23, depending on miscellaneous conditions, for example, the viscosity of the liquid material of the pressing piece layer 30. Therefore, a hole filling material is formed, and the key sheet 1 sometimes has the hole filling material. This hole filling material, needless to say, has the light transmitting properties. All of the holes do not have to be filled with the hole filling material. This hole filling material 13 is sometimes not formed.

The pressing piece layer 30 is formed of a transparent material or the like and has light transmitting properties so that the light with which the key sheet 1 is irradiated from the downside passes through the light transmitting display portion.

When the key 12 is pressed with a finger, the key 12 moves downwards (tilts in the case of the directional input of the multidirectional key 12t), the key top portion 10, the metal plate 20 and the pressing piece layer 30 are deformed, and the pressing piece 32 presses the click sense generating portion to deform the portion. In consequence, the click sense is generated. Moreover, when the finger is detached from the key 12, the key sheet 1 returns to a state before the pressing operation by the restoring force of one of the key top portion 10, the metal plate 20, the pressing piece layer 30 (in a case where the layer as the base portion 31) and the click sense generating portion (in a case where the pressing piece 32 abuts on the sheet). The shape (the thickness or the like), the material and the like of the key top portion 10, the metal plate 20, the pressing piece layer 30 or the like is determined so that the key 12 can perform such a pressing operation, to form the key sheet 1. Since the key sheet 1 is provided with the rigidity and the shape stability, the key sheet is incorporated in the device so that a large part of the key sheet 1 is exposed from an operation opening which does not have any partition.

Since the key top portion 10 has the light transmitting properties as described above, the key sheet 1 has the metallic color, and the surface of the sheet becomes three-dimensional. Moreover, when the plurality of keys 12 are formed by the printing or the insertion molding, for the sake of the convenience of the forming method, a thin portion is unavoidably formed between the keys 12 and around the keys 12. When this thin portion is regarded as a portion other than a portion of the sheet-like base portion 11 right under the key 12, the key top portion 10 can easily be formed by the above printing, the insertion molding or the like. Thus, the key top portion 10 has the sheet-like base portion 11, and the plurality of keys 12 each formed in the protruding shape on the surface of this sheet-like base portion 11, and this key top portion 10 is secured to the surface of the metal plate 20. Therefore, a method such as the printing or the insertion molding can be used in forming the key top portion 10. This obviates the need for the positioning of the key top portion or the like which has raised a problem in a case where the key top portion is directly formed only on a portion of the metal plate 20 corresponding to the key. Therefore, the key sheet can easily be formed. Furthermore, since the protruding portions constitute the keys 12, a boundary between the keys 12 becomes clear, and the keys 12 can clearly be recognized. In consequence, the region other than the key 12 is not pressed, and hence the key sheet has satisfactory operability. As described above, this key sheet 1 can give a new impression that the sheet has the metallic color but has a three-dimensional effect. Moreover, the key sheet can easily be formed, and has further satisfactory operability.

The character, the symbol or the figure of the display portion 22 is formed of the set of a large number of light transmitting holes, especially the slit-like light transmitting holes 23, whereby this display portion 22 gives a newer impression. Furthermore, since the character, the symbol or the figure of the display portion 22 is formed by arranging the linear slit-like light transmitting holes 23a, 23b, 23c, . . . in parallel with one another, this display portion 22 gives a new impression. Here, the linear slit-like light transmitting hole 23 may have several recesses or protrusions as in the slit-like light transmitting hole 23. Moreover, in a case where the character, the symbol or the figure of the display portion 22 is formed of the set of a large number of light transmitting holes as the slit-like light transmitting holes 23 and the character or the like of this display portion 22 is a character or the like having a region which might fall at a time when this character or the like is represented by one through hole, this character or the like does not have to be represented by the through hole having the shape of a cut character or the like. Therefore, the display portion 22 giving the new impression can be formed. Thus, the key sheet 1 is a key sheet giving the newer impression.

When at least a part of the periphery of the light transmitting hole (the slit-like light transmitting hole 23) is colored, the display portion 22 becomes colorful, and the display portion 22 gives the new impression. In particular, when the portion between the adjacent light transmitting holes is colored, the peripheral portion of the light transmitting hole is colored so as to form the edge of the character, the symbol or the figure of the display portion 22, or both of the portions are colored, the display portion 22 gives the new impression. In particular, the display portion 22 gives the newer impression by the synergistic effect of the colored region and the light transmitting hole. Therefore, this key sheet 1 is a metallic key sheet having the newer design.

Since the key 12 formed in the protruding shape forms the protruding portion, the operator of the key 12 can recognize the key 12 by the protruding portion. Therefore, the region of the key 12 does not have to be recognized by the operator on the metal plate 20 side, and the metal plate 20 can be designed (the position, size, shape or the like of the display portion 22) freely to a certain degree.

Since the key 12 is the protruding portion, the click sense is sometimes easily transmitted as compared with a case where the key sheet has a flat surface. In consequence, the operability of the key sheet 1 improves. This can be said especially in a case where the key top portion 10 is hard.

The key 12 is the protruding portion and the peripheral portion of the key is a thin portion (the sheet-like base portion 11). Therefore, when the key 12 is pressed, the key is deformed from the boundary between the protruding portion and the thin portion to the peripheral region of the boundary (the peripheral portion on the thin portion side), and the key 12 moves downwards (when the key 12 is the multidirectional key, the key tilts). In consequence, the area of the pressing region of the key top portion 10 for pressing the metal plate 20 during the pressing operation of the key 12 increases. Therefore, the operability improves. For example, to easily press the key, a partition groove for separating the key or the like does not have to be formed in the metal plate. This applies especially to a case where the key top portion 10 is hard.

It is to be noted that the display portion 22 does not have to be provided on the metal plate 20, and may be provided on the key top portion 10 (especially the surface of the key 12). Such a key sheet has novel design. The key sheet in which the display portions are provided on the surfaces of the keys 12 and in which the key top portion 10 has the light transmitting properties has three-dimensional novel design. In this case, to illuminate the display portions, the metal plate 20 may be provided with the light transmitting holes. The key top portion 10 or the metal plate 20 may be subjected to another decoration other than the above-mentioned decoration. The hole filling material 13, the key top portion 10 and the pressing piece layer 30 may appropriately not have the light transmitting properties.

### Second Embodiment

In the first embodiment, the key top portion 10 is directly formed on the surface of the metal plate 20 by printing, insertion molding or the like, but in a second embodiment, the light transmitting key top portion 10 may beforehand be formed as a separate portion made of a single synthetic resin as a material, and the key top portion is secured to the surface of the metal plate 20 by use of an adhesive, a sticky material or the like. In consequence, as shown in FIG. 5, a material corresponding to the hole filling material 13 is not formed. However, the hole filling material (e.g., having light transmitting properties) may separately be formed.

A light transmitting key top portion 110 may be constituted by forming the upper portions of keys 112 and a sheet-like base portion 111 on the surface of a base such as a polyurethane terephthalate (PET) sheet or an urethane sheet (corresponding to the lower portion of the sheet-like base portion 111 in this case) by printing, insertion molding or the like. In the upper portions of the keys 112 and the sheet-like base portion 111, a hard synthetic resin such as an electromagnetic setting resin is used as a material. To harden the material, the upper portions of the keys 112 and the sheet-like base portion 111 are fused, and directly secured to the base. To increase securing strength, the surface of the base may be subjected to a chemical or physical surface (reforming) treatment.

The light transmitting key top portion 110 may be formed by directly securing a plurality of keys 112 beforehand formed by injection or the like as separate members to the surface of the above base (corresponding to the sheet-like base portion 111 in this case) by use of the adhesive, the sticky material or the like. To increase the securing strength, the securing surfaces of the base and/or the keys 112 may be subjected to the chemical or physical surface (reforming) treatment.

To increase the securing strength, the back surface of the light transmitting key top portion 110 and the surface of a metal plate 120 may be subjected to the chemical or physical surface (reforming) treatment.

As described above, the light transmitting key top portion 110 is beforehand separately formed and is secured to the surface of the metal plate 120 by use of securing means such as the adhesive or the sticky material. This obviates the need for the positioning of the key top portion which has raised a problem in a case where the key top portion is directly formed only on a portion of the metal plate 120 corresponding to the key. The key sheet can easily be formed.

The description of the other constitutional requirements (including the light transmitting key top portion 110) of the present embodiment or the like conforms to the first embodiment, and hence the description is omitted. It is to be noted that in FIG. 5, constitutional requirements corresponding to those of the first embodiment are denoted with reference numerals in which 100 has been added to those of the first embodiment.

### Modification of First or Second Embodiment

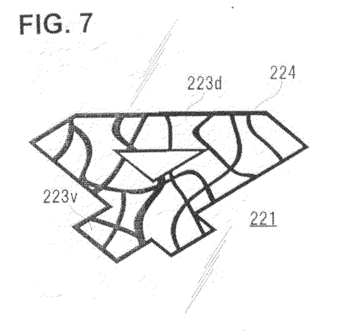

In the first or second embodiment, the plurality of slit-like light transmitting holes 23 are formed in parallel, but the holes do not necessarily have to be formed so that the adjacent slits are parallel to each other. Moreover, as shown in, for example, FIG. 6 or 7, the light transmitting hole may be a set of worm-eaten light transmitting holes 223. In the present modification, as the light transmitting hole, the worm-eaten light transmitting hole 223 is employed. It is to be noted that the light transmitting holes may be comparatively small dots each having a regular shape such as a circular shape or a polygonal shape.

A set of a large number of worm-eaten light transmitting holes 223 is a set of amorphous light transmitting holes (see FIGS. 6 and 7) in which at least a part of the light transmitting holes of this set have different sizes and shapes.

A character, a symbol or a figure of a display portion 22 is formed of worm-eaten light transmitting holes 223a, 223b, 223c, . . . formed in a metal thin plate 221.

Furthermore, as shown in FIG. 7, a portion between the adjacent worm-eaten light transmitting holes 223 is appropriately colored by printing, painting or the like. In addition, as shown in FIG. 7, the periphery of the worm-eaten light transmitting hole 223 is colored so as to form the edge of a numeral “4”, that is, to form the edge of the character, the symbol or the figure of the display portion. Therefore, the display portion 22 has a colored region 224 obtained by coloring the surface of the metal thin plate 221. It is to be noted that at least a part of the periphery of the worm-eaten light transmitting hole 223 may be colored.

Since the light transmitting hole is the worm-eaten light transmitting hole 223, a display portion giving a new impression different from that in a case where a slit-like light transmitting hole is employed as the light transmitting hole can be formed. Therefore, the key sheet of this modification is a key sheet giving a new impression different from that in a case where the slit-like light transmitting hole is employed as the light transmitting hole. Moreover, since at least a part of the periphery of the worm-eaten light transmitting hole 223 is colored, the display portion giving a new impression different from that in a case where the slit-like light transmitting hole is employed as the light transmitting hole can be formed. This key sheet of this modification is a key sheet giving a new impression different from that in a case where the slit-like light transmitting hole is employed as the light transmitting hole.

It is to be noted that the worm-eaten light transmitting hole 223 is a generic representation of worm-eaten light transmitting holes 223a, 223b, 223c . . . , and is one of the plurality of worm-eaten light transmitting holes.

The description of the other constitutional requirements, effect and the like conforms to the above description in a case where the slit-like light transmitting hole is used as the light transmitting hole, and hence the description is omitted.

1. A key sheet having a plurality of keys, comprising:
a metal plate; and
a key top portion secured to the surface of the metal plate so as to cover a large part of the metal plate,
the key top portion having a sheet-like base portion and the plurality of keys each formed in a protruding shape on the surface of this sheet-like base portion.

2. The key sheet according to claim 1, wherein the metal plate has a plurality of display portions corresponding to the plurality of keys, respectively, and
the key top portion has light transmitting properties so that at least a part of the metal plate including the display portions is visually recognized via this key top portion.

3. The key sheet according to claim 1, wherein the keys are positioned away from one another.

4. The key sheet according to claim 2, wherein a character, a symbol or a figure of the display portion is formed of a set of a large number of light transmitting holes.

5. The key sheet according to claim 4, wherein the light transmitting holes are slit-like light transmitting holes.

6. The key sheet according to claim 4, wherein the light transmitting holes are worm-eaten light transmitting holes.

7. The key sheet according to claim 4, wherein at least a part of the peripheries of the light transmitting holes is colored.

8. The key sheet according to claim 1, wherein a plurality of pressing pieces are disposed on the back surface side of the metal plate.
